(19) United States
(12) Patent Application Publication
(10) Pub. No.: US 2006/0128108 A1
(43) Pub. Date: Jun. 15, 2006

(54) Method for forming a titanium nitride layer and method for forming a lower electrode of a MIM capacitor using the titanium nitride layer

(75) Inventors: Kyong-Min Kim, Ansan-si (KR); Dong-Jun Kim, Cheonan-si (KR); Byoung-Dong Kim, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/297,939

(22) Filed: Dec. 9, 2005

(30) Foreign Application Priority Data
Dec. 9, 2004 (KR) 2004-103523

(51) Int. Cl. H01L 21/20

(52) U.S. Cl. 438/381

(57) ABSTRACT

A method is provided for forming a titanium nitride layer in a metal-insulator-metal (MIM) capacitor. The deposition of a titanium nitride layer is carried out by means of an MOCVD method using a metallo-organic material as a source gas, followed by a rapid thermal process (RTP) at a high temperature. Through the RTP, impurities in the titanium nitride layer are removed and a surface area of the titanium nitride layer is increased in comparison with the titanium nitride layer before the RTP. The titanium nitride layer with increased surface area is useful for a lower electrode of a MIM capacitor.

### BACKGROUND OF THE INVENTION

1. Field of the Invention

The present invention relates to a method for forming a titanium nitride layer, and more particularly, a method for forming a metal-insulator-metal (MIM) capacitor using a titanium nitride layer.

2. Description of the Related Art

Generally, a capacitor is configured with two conductive electrodes and an insulator interposed in between. The capacitor is a passive element that can store energy in the form of an electrical charge by means of a bias voltage applied to the electrodes. Typically, a single crystalline silicon or a poly-crystalline silicon (hereinafter, referred to as a ‘polysilicon’) is used for the electrodes of the capacitor. The single crystalline silicon or the polysilicon, however, shows a limitation in reducing the resistance of the capacitor electrodes due to its material characteristic. This material characteristic limitation is manifested when a bias voltage is applied to the capacitor electrodes made of the single crystalline silicon or polysilicon resulting in a deficient constant capacitance due to a generation of a depletion region and an unstable voltage in the capacitor. To overcome this limitation, a metal insulator metal (MIM) capacitor is used in place of the single crystalline silicon or polysilicon for the capacitor electrode.

A MIM capacitor is generally used in the fabrication of a precise analog product and a memory device. The advantages of a MIM capacitor include its independence of a bias voltage and its excellent capacitance gradient in different ranges of voltage or temperature.

Currently, there are known methods for forming the MIM capacitor using a titanium nitride layer as a lower electrode thereof. One method is the chemical vapor deposition (CVD) method which is used to form the titanium nitride layer for the lower electrode of the MIM capacitor using titanium tetra chloride (TiCl₄) as a titanium source and ammonia (NH₃) gas as a nitrogen source. Another method is by means of a metallo-organic CVD (MOCVD) method using tetrakis-dimethylamino titanium (TDMAT, Ti[N(CH₃)₂]₄).

High temperature in a range of about 500° C. to about 700° C. is used for the deposition of the titanium nitride layer using the CVD method. The resulting by-product of this process is chlorine gas, which may diffuse into an impurity region of the semiconductor substrate constituting n-type/p-type impurities. In turn, these impurities may diffuse out of the impurity region of the substrate and eventually deteriorate the characteristic of a transistor which may constitute a logic area of a device.

While the other deposition method, MOCVD using TDMAT, also has inherent process impurities comprising carbon, hydrogen and chlorine. These impurities may deteriorate the characteristics of the titanium nitride layer due to an increase in its resistivity. In addition, said impurities may react with a dielectric layer of the ensuing product capacitor, leading to an increase in leakage current. Hence, it is essential to develop a new method for forming a lower electrode using an enhanced titanium nitride layer.

Similarly, a popular method used in forming the capacitor electrode of a polysilicon insulator polysilicon (PIP) capacitor using a single crystalline silicone or polysilicon is intended to increase a surface area of the silicon lower electrode by forming hemispheral silicon grains thereon. This technique is used to obtain high capacitance. However, this approach of forming a metal lower electrode with an increased surface area to secure a high capacitance has yet to be tried. Hence, said approach needs to be developed.

### SUMMARY OF THE INVENTION

Embodiments of the present invention provide methods for forming an enhanced titanium nitride layer with an increased surface area. The methods for forming the titanium nitride layer include a deposition process of the titanium nitride layer and an annealing process.

The deposition process of the titanium nitride layer is carried out by a metallo-organic chemical vapor deposition (MOCVD) using tetrakis-dimethylamino titanium (TDMAT, Ti[N(CH₃)₂]₄). The annealing process is carried out to increase a surface area of the deposited titanium nitride layer at a predetermined temperature to induce an agglomeration phenomenon in the deposited titanium nitride layer. In addition, during the annealing process, impurities in the titanium nitride layer deposited by the MOCVD are removed.

For example, the annealing process is performed by a rapid thermal process (RTP), which results in removing the impurities and inducing an agglomeration phenomenon in the deposited titanium nitride layer. Subsequently, the surface area of the titanium nitride layer may be increased.

In a preferred embodiment of the invention, the MOCVD is carried out at a temperature of about 300° C. to about 400° C.

In a preferred embodiment of the invention, the RTP is carried out in an ambient ammonia gas at a concentration of about 20 sccm to about 100 sccm provided that there is a deposition temperature of about 600° C. to about 700° C. and a deposition pressure of about 0.2 torr to about 2 torr. Consequently, carbon and hydrogen impurities in the titanium nitride layer are removed in the form of a C_{X}H_{Y} gas or a HNR gas, respectively, wherein R may be carbon and hydrogen organic material. Additionally, an agglomeration phenomenon of the titanium nitride layer during the RTP is generated, whereby the surface area of the titanium nitride layer is increased. Further, the agglomeration phenomenon results in the removal of the impurities in the deposited titanium nitride layer.

According to the embodiment of the present invention, the titanium nitride layer produced with the aforementioned method has a good quality and an increased surface area which makes it useful for forming the lower electrode of a MIM capacitor.

In another embodiment of the present invention, the RTP at a high temperature of about 600° C. to about 700° C., is preferably performed for a short period in order to prevent diffusion of impurities out of an impurity region of the transistor. For example, the RTP may be carried out for any short period, but preferably, for about 10 seconds to about 60 seconds.

In yet another embodiment of the present invention, the method of forming an MIM capacitor using the lower electrode of the titanium nitride layer having the increased surface area, comprises sequentially stacking a dielectric layer and an upper electrode on the lower electrode after forming said titanium nitride layer. The dielectric layer may be made of layers comprising hafnium oxide (HfO₂) layer, but preferably made of multilayers of sequentially stacked aluminum oxide (Al₂O₃) and a hafnium oxide layers; or similar compositions or combinations thereof.

In another preferred embodiment of the present invention, the upper electrode, for example, may be made of a titanium nitride layer. The upper electrode of the titanium nitride layer may be formed by the same method according to the embodiment of the present invention for forming the titanium nitride layer for the lower electrode. However, unlike the lower electrode, the upper electrode may not require the RTP to increase its surface area. Instead, it is preferable to carry out an annealing process for removing impurities in the titanium nitride layer for the upper electrode at a low temperature, for example, with the use of a plasma annealing process. The plasma annealing process comprises: carrying out the annealing process at a temperature of about 300° C. to about 400° C. in an ambient plasma incorporating nitrogen plasma and hydrogen plasma therein. The operations of deposition of the titanium nitride layer and the plasma annealing process may be repeated to form the titanium nitride layer to reach a desired thickness for the upper electrode.

In still another preferred embodiment of the invention, after forming the upper electrode, a physical vapor deposition (PVD) method may be used to form another titanium nitride layer on said upper electrode. Said another titanium nitride layer protects the capacitor from post fabrication processes.

The present invention will be easily understood with references to the drawings and the preferred embodiments thereof. The invention may, however, be embodied in many different forms and should not be construed as being limited to the embodiments set forth herein; rather, these embodiments are provided so that this disclosure will be thorough and complete, and will fully convey the concept of the invention to those skilled in the art.

While terms of ‘first’, ‘second’, ‘third’ and so forth are used for illustrating various layers or regions in the preferred embodiments of the present invention, the layers or the regions should not be limited to these terms. In addition, these terms are merely used for distinguishing a predetermined layer or a predetermined region from another predetermined layer or a predetermined region in the same embodiment of the present invention. Further, a first layer described in one embodiment of the present invention may be referred to as a second layer in another embodiment of the present invention.

Further, it is provided that when one layer is disposed on another layer or a substrate, that said layer maybe directly formed on another layer or said substrate; or indirectly formed on said another layer or said substrate wherein a third layer may be interposed between said layer and said another layer or said substrate. Furthermore, thickness of layers and regions are exaggerated in the drawings for clarity.

### BRIEF DESCRIPTION OF THE DRAWINGS

The accompanying drawings, which are included to provide a further understanding of the invention and are incorporated herein and constitute a part of this application, illustrate preferred embodiments of the present invention and together with the description serve to explain the principle of the invention. In the drawings:

FIG. 1 is a flow chart illustrating a method for forming a titanium nitride layer according to an embodiment of the present invention;

FIGS. 2 and 3 are cross-sectional views illustrating a method for forming the titanium nitride layer according to a preferred embodiment of the present invention; and

FIGS. 4 to 7 are cross-sectional views illustrating a method for forming a metal-insulator-metal (MIM) capacitor having a lower electrode of the titanium nitride layer according to the preferred embodiments of the present invention.

### DETAILED DESCRIPTION OF PREFERRED EMBODIMENTS

Detailed references to the preferred embodiments of the present invention will now be made; examples of which are illustrated in the accompanying drawings. However, the present invention is not limited to the embodiments illustrated hereinafter, where the embodiments herein are introduced for understanding the scope and spirit of the present invention.

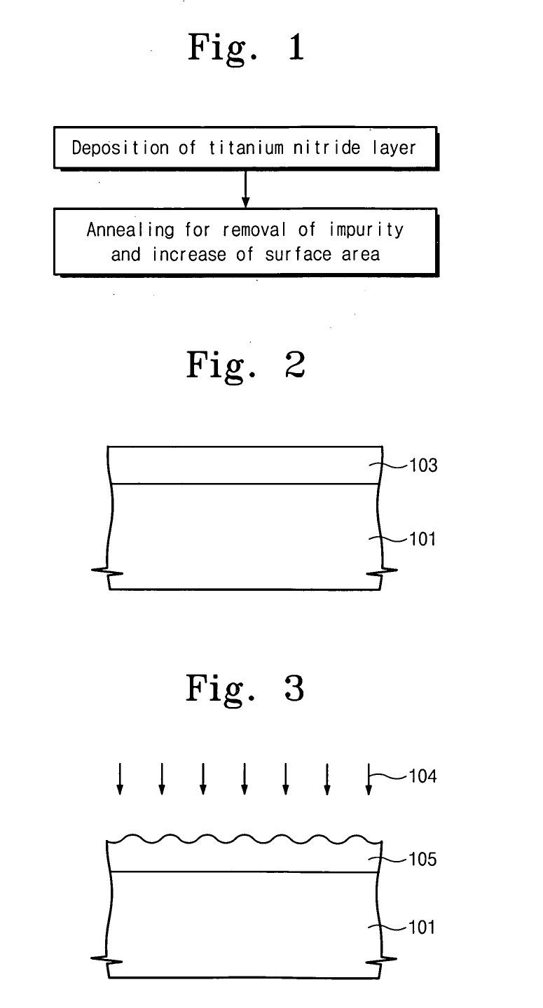

FIG. 1 is a flow chart of fabrication process illustrating a method for forming a titanium nitride layer according to a preferred embodiment of the present invention.

The above method comprises: forming a titanium nitride layer by using a metallo-organic chemical vapor deposition (MOCVD) method; then carrying out a rapid thermal process (RTP) on the deposited titanium nitride layer; and during the RTP, removing the residual impurities in the deposited titanium nitride layer and resulting in a soft roughness with increased surface area of the deposited titanium nitride layer.

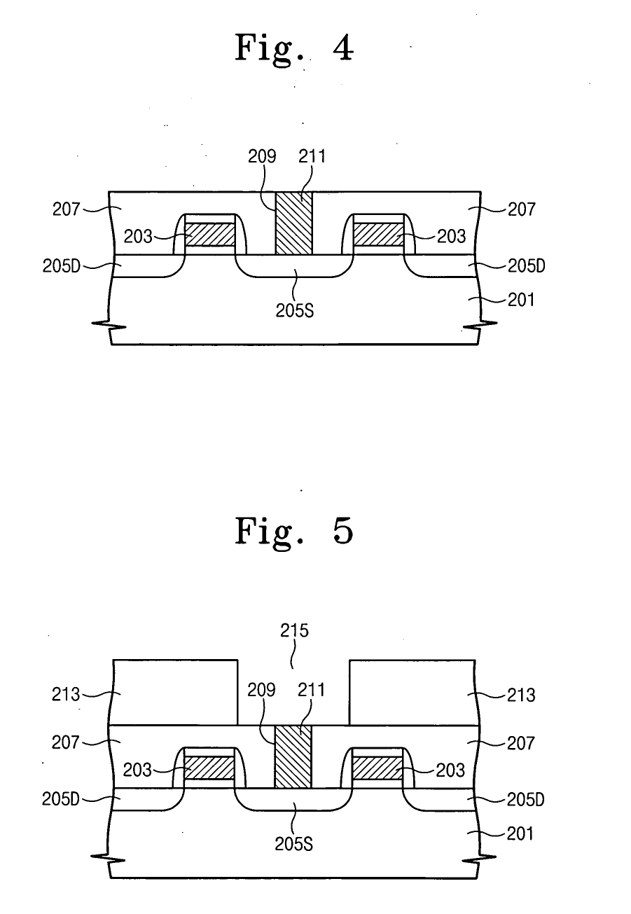

FIG. 2 and FIG. 3 show the details of a method for forming the titanium nitride layer according to a preferred embodiment of the present invention.

In FIG. 2, a titanium nitride layer 103 is deposited on a substrate 101. The substrate may be an arbitrary semiconductor based structure having a silicon surface. For example, the semiconductor-based structure comprises a silicon, a silicon on insulator (SOI), doped or undoped silicon, a silicon epitaxial layer supported by a semiconductor structure, silicon-germanium (SiGe), germanium or gallium-arsenide (GaAs), or other semiconductor structures or combinations thereof. The substrate used in the embodiment of the present invention may be a substrate pre-manufactured prior to incorporation herein through any of the processes comprising an ion implantation process, a device isolation process, an impurity diffusion process, a process for forming a metal oxide semiconductor field effect transistor (MOSFET) or a process of depositing a thin film such as an insulating layer or a conductive layer or any similar method or combinations thereof.

Whereas, the titanium nitride layer 103 may be formed by a chemical vapor deposition (CVD) method or a metallo-organic CVD (MOCVD) method. A tetrakis-dimethylamino titanium (TDMAT) or tetrakis-diethylamino titanium (TEMAT, TiN[CH₂(CH₃)₂]₄) is used as a metallo-orgnaic precursor. The deposition temperature using the MOCVD, in forming the titanium nitride layer using the metallo-organic precursor is lower relative to the CVD using TiCl₄ and NH₃. The deposition process using MOCVD is carried out at a deposition temperature of about 300° C. to about 400° C. and a deposition pressure of about 0.2 torr to about 2 torr.

Referring to FIG. 3, a rapid thermal process (RTP) is carried out to remove impurities in the titanium nitride layer 103 and to increase its surface area. The RTP is carried out in an ambient gas, preferably ammonia gas (NH₃) or an ambient mixture of nitrogen gas and hydrogen gas. Preferably, the RTP is carried out in ambient ammonia gas at a temperature of about 600° C. to about 700° C. for a period of about 10 seconds to about 60 seconds. The concentration of the ammonia gas is preferably maintained at about 20 sccm to about 100 sccm.

The titanium nitride layer deposited by the MOCVD may have a chemical formula composition, which may be represented by TiC_{X}N_{Y}H₂, which may have impurities comprising carbon and hydrogen.

Through the RTP in ambient ammonia gas, a possible chemical reaction is shown below, wherein the impurities in the titanium nitride layer 103 may be removed resulting in a titanium nitride layer 105 with an enhanced surface area.
TiC_{X}N_{Y}H₂+NH₃→TiN+C_{X}H_{Y}↑+HNR↑

Where R may stand for a carbon-hydrogen-containing-material.

The impurities possibly comprising carbon and hydrogen in the titanium nitride layer react with the ambient ammonia during RTP and may be converted into gaseous compounds, which may be represented as C_{X}H_{Y} and HNR respectively and subsequently, these impurities may be removed from the titanium nitride layer.

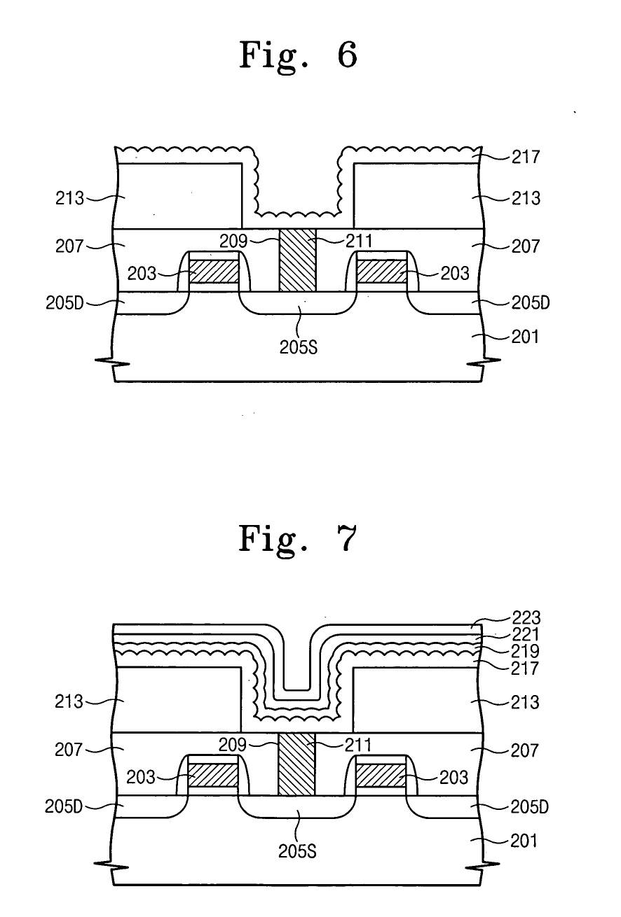

A method for forming a metal-insulator-metal (MIM) capacitor using the titanium nitride layer fabricated by the aforementioned method is illustrated in FIGS. 4 through 7. A lower electrode of the MIM capacitor in the preferred embodiments of the present invention is represented by a cylindrical shape for illustrative purposes; however, the lower electrode may be fabricated in various known shapes.

A substrate shown in FIG. 4 may have been manufactured using any of the processes comprising an ion implantation process, a device isolation process and a process for forming a MOSFET. For example in FIG. 4, the MOSFET provided with a gate 203 and source/drain 205S and 205D is formed on the semiconductor substrate 201. The gate 203 is electrically isolated from the semiconductor substrate 201 by means of an insulating layer such as a thermal oxide layer. The source/drain 205S and 205D may be formed by implanting impurities such as n-type dopant or p-type dopant and subsequently carrying out an annealing process. After forming the MOSFET, a first interlayer dielectric layer 207 is formed and is patterned into a predetermined configuration through a photolithography process which exposes the source 205S and thereby allow to form a contact hole 209. Then, a conductive material is filled into the contact hole 209 to form a contact plug 211. In the preferred embodiments of the invention, the present first interlayer dielectric layer 207 may include the above illustration and may further be made of materials comprising borophosphosilicate glass (BPSG) doped with boron and phosphor, boronsilicate glass doped with boron (BSG), phosphorsilicate glass (PSG) doped with phosphor and similar compositions or combinations thereof.

In FIG. 5, a second interlayer dielectric layer 213 is formed wherein a trench 215 defining a region wherein a lower electrode in a post process is formed over the resultant. The height of a lower electrode depends on the thickness of the second interlayer dielectric layer 213. A typical photolithography process may be one method used for forming the trench 215 in the second interlayer dielectric layer.

Similarly, the second interlayer dielectric layer 213 described and shown above may be made of a material comprising BPSG doped with boron and phosphor, BSG doped with boron, PSG doped with phosphor, tetraethylorthosilicate glass (TEOS) and similar compositions or combinations thereof.

Preferably, the trench 215 may be formed as wide as possible without being connected to its neighboring trenches in order to secure high capacitance. The trench 215 may be formed preferably at a substantial distance as short as possible from its neighboring trenches.

In FIG. 6, the formation of an impurity-free titanium nitride layer 217 is shown with a surface area increased by the aforementioned method illustrated in FIGS. 1 through 3. The aspect ratio, i.e., the ratio between height and width, of the trench 215 helps determine the resulting thickness of the titanium nitride layer 217. For example, the thickness of the titanium nitride layer 217 may be any thickness, but preferably about 200 Å to about 400 Å.

In FIG. 7, the formation of a dielectric layer 219 and an upper electrode 221 on the titanium nitride layer 217 is shown. Herein, the dielectric layer 219 may be made of an insulating material with a high dielectric constant from the group comprising hafnium oxide (HfO₂), aluminum oxide (Al₂O₃), zirconium oxide (ZrO₂), hafnium-aluminum-oxygen alloy (Hf—Al—O), or lanthanum-aluminum-oxide alloy (La—Al—O) or similar compositions and combinations thereof.

As an illustration, the dielectric layer 219 of double layers provided with an aluminum oxide layer and a hafnium oxide layer is herein discussed.

First, the aluminum oxide layer is formed on the titanium nitride layer 217, wherein the aluminum oxide layer may be formed by any of the methods comprising CVD, a MOCVD, a sputtering method or an atomic layer deposition (ALD) method or similar methods or combinations thereof. For example, in forming the aluminum oxide layer by the ALD method, trimethylaluminum (TMA) is used as an aluminum precursor and ozone (O₃) is used as an oxygen precursor. After flowing TMA gas into a reaction chamber, nitrogen gas is supplied into the reaction chamber to purge the reaction chamber. Thereafter, ozone is supplied into the reaction chamber to form an aluminum oxide layer. Then, nitrogen gas is again supplied into the reaction chamber. By repeating the above operations, the aluminum oxide layer of a desired thickness, but preferably of the thickness of about 10 Å to about 30 Å is formed. During the ALD, the deposition temperature is maintained at about 300° C. to about 500° C.

Next, a hafnium oxide layer of a desired thickness, but preferably of about 30 Å to about 60 Å thick is formed on the aluminum oxide layer. Likewise, the hafnium oxide layer may also be formed by any of the methods comprising a CVD, a MOCVD, a sputtering method or an ALD method or similar methods or combinations thereof. For example, in forming the hafnium oxide layer by the ALD method, a tetraethylmethylaminehafnium (TEMAH) is used as a hafnium precursor and an ozone (O₃) gas is used as an oxygen precursor. After flowing TEMAH gas into a reaction chamber, nitrogen gas is supplied into the reaction chamber to purge the reaction chamber. Thereafter, ozone is supplied into the reaction chamber to form a hafnium oxide layer. Then nitrogen gas is again supplied into the reaction chamber. By repeating the above operations, the hafnium oxide layer of a desired thickness, preferably of the thickness of about 30 Å to about 60 Å is formed. During the ALD, the deposition temperature is maintained at about 250° C. to about 350° C.

Similarly, the upper electrode 221 of a desired thickness may be formed by repeating the operations of a deposition process of titanium nitride layer and a plasma annealing process. The thickness of the titanium nitride layer may be any thickness, but preferably at about 200 Å to about 400 Å. The deposition of titanium nitride layer may be performed by means of the MOCVD using TDMAT as a precursor with the deposition temperature at about 300° C. to about 400° C. and the deposition pressure at about 0.2 torr to about 2 torr. The plasma annealing process after the deposition is carried out in ambient plasma mixture of nitrogen and hydrogen at a temperature lower than the temperature of the RTP. Here, the plasma may be generated by known methods, which may include, for example, plasma generated by applying high frequency power at a range of about 50 watt to about 400 watt after flowing a mixture of nitrogen gas and hydrogen gas into the reaction chamber. The plasma annealing process after the deposition of titanium nitride layer results in the removal of the impurities in the deposited titanium nitride layer. Subsequently, the quality of the dielectric layer 219 is enhanced.

Although the upper electrode 221 is formed by repeating the operations of a deposition process and a plasma annealing process, the upper electrode may be formed by only one method of a deposition process and a RTP after the deposition. A titanium nitride layer 223 may be formed on the upper electrode 221 by means of a physical vapor deposition (PVD) method. The titanium nitride layer 223 may protect the MIM capacitor from post fabrication processes. This step is a selective fabrication process and may be performed as necessary.

Thus, the aforementioned method in the preferred embodiments of the present invention of forming the titanium nitride layer of the MIM capacitor, where said titanium nitride layer has an increased surface area leads to an enhanced characteristic of a MOSFET of the logic area.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method for forming a titanium nitride layer, comprising:
forming a titanium nitride layer on a substrate; and
carrying out an annealing process for removing impurities in the titanium nitride layer and increasing surface area of the titanium nitride layer.

2. The method of claim 1, wherein the titanium nitride layer is deposited by a metallo-organic chemical vapor deposition (MOCVD) using tetrakis-dimethylamino titanium (TDMAT, Ti[N(CH₃)₂]₄) as a precursor and a temperature of about 300° C. to about 400° C. and a pressure of about 0.2 torr to about 2 torr.

3. The method of claim 1, wherein the annealing process is a rapid thermal process carried out in an ambient ammonia gas at a temperature of about 600° C. to about 700° C. for a period of about 10 seconds to about 60 seconds.

4. The method of claim 1, wherein the titanium nitride layer is deposited by an MOCVD and the annealing process is a rapid thermal process.

5. The method of claim 4, wherein the MOCVD is carried out using TDMAT as a precursor with a temperature of about 300° C. to about 400° C. and a pressure of about 0.2 torr to about 2 torr and the rapid thermal process is carried out with an ambient ammonia gas at a temperature of about 600° C. to about 700° C. for a period of about 10 seconds to about 60 seconds.

6. The method of claim 1, further comprising forming a dielectric layer and a conductive layer after carrying out the annealing process.

7. The method of claim 6, wherein the dielectric layer is selected from the group comprising a hafnium oxide (HfO₂) layer, an aluminum oxide (Al₂O₃) layer, a double layer of HfO₂ and Al₂O₃, a zirconium oxide (ZrO₂) layer, a hafnium-aluminum-oxygen alloy (Hf—Al—O), or a lanthanum-aluminum-oxide alloy (La—Al—O) or similar compositions and combinations thereof.

8. The method of claim 6, wherein the conductive layer is formed by repeating a deposition process of the titanium nitride layer and a plasma annealing process, using the MOCVD.

9. The method of claim 8, wherein the MOCVD is carried out by using TDMAT as a precursor at a temperature of about 300° C. to about 400° C. and a pressure of about 0.2 torr to about 2 torr and the plasma annealing process is carried out in an ambient nitrogen and hydrogen plasma.

10. The method of claim 6, wherein the conductive layer is formed by means of a physical vapor deposition (PVD) method.

11. A method for forming a metal-insulator-metal (MIM) capacitor comprising:
forming a titanium nitride layer for a lower electrode on a substrate;
carrying out a rapid thermal process to remove impurities in the titanium nitride layer for the lower electrode and to increase a surface area thereon;
forming a dielectric layer; and
forming a titanium nitride layer for an upper electrode.

12. The method of claim 11, wherein the titanium nitride layer for the lower electrode is formed by an MOCVD using TDMAT (Ti[N(CH₃)₂]₄) as a precursor and the rapid thermal process is carried out in an ambient ammonia gas.

13. The method of claim 12, wherein the MOCVD is carried out at a temperature of about 300° C. to about 400° C. and a pressure of about 0.2 torr to about 2 torr and the rapid thermal process is carried out at a temperature of about 600° C. to about 700° C. for a period of about 10 seconds to about 60 seconds in ambient ammonia gas at a concentration of about 20 sccm to about 100 sccm.

14. The method of claim 11, wherein the titanium nitride layer for the upper electrode is formed by repeating a deposition process of the titanium nitride layer using TDMAT and a plasma annealing process.

15. The method of claim 14, wherein the MOCVD is carried out at a temperature range of about 300° C. to about 400° C. and a pressure range of about 0.2 torr to about 2 torr and the plasma annealing process is carried out in ambient nitrogen and hydrogen plasma.

16. An MIM capacitor comprising:
a lower electrode of a titanium nitride layer having a rough surface thereon;
a dielectric layer disposed on the lower electrode of the titanium nitride layer; and
an upper electrode of a titanium nitride layer disposed on the dielectric layer.

17. The MIM capacitor of claim 16, wherein the lower electrode of the titanium nitride layer is formed by carrying out a rapid thermal process in an ambient ammonia gas after forming the titanium nitride layer by means of the MOCVD using TDMAT.

18. The MIM capacitor of claim 16, wherein the upper electrode of the titanium nitride layer is formed by repeating the MOCVD and an annealing process, wherein the MOCVD is carried out using the TDMAT and the annealing process is carried out in an ambient nitrogen and hydrogen plasma.

19. The NIM capacitor of claim 18, wherein the upper electrode of the titanium nitride layer has a thickness of about 200 Å to about 400 Å.

20. The MIM capacitor of claim 16, wherein the dielectric layer further comprises a trench with an aspect ratio.
